(19) United States
(12) Patent Application Publication
(10) Pub. No.: US 2026/0342341 A1
(43) Pub. Date: Oct. 29, 2026

(54) Digitally Controlled Oscillator with Differential Varactor Circuit

(71) Applicant: Infineon Technologies AG, Neubiberg (DE)

(72) Inventors: Alessandro Garghetti, Villach (AT); Davide Bello, Villach (AT); Davide Manente, Mira (IT); Giovanni Steffan, Villach (AT)

(21) Appl. No.: 19/187,356

(22) Filed: Apr. 23, 2025

(51) Int. Cl. H03L 7/091; H03L 7/099

(52) U.S. Cl. CPC H03L 7/091; H03L 7/0992

(57) ABSTRACT

A digitally-controlled oscillator (DCO) includes: a digital-to-analog converter (DAC) configured to generate a differential output signal; and a differential varactor circuit that includes: a first input terminal and a second input terminal coupled to the DAC and configured to receive the differential output signal of the DAC; a first capacitor terminal and a second capacitor terminal; a first varactor and a second varactor, where an anode of the first varactor and an anode of the second varactor are coupled to the second input terminal; a first capacitor coupled between a cathode of the first varactor and the first capacitor terminal; a first resistor coupled between the cathode of the first varactor and the first input terminal; a second capacitor coupled between a cathode of the second varactor and the second capacitor terminal; and a second resistor coupled between the cathode of the second varactor and the first input terminal.

### TECHNICAL FIELD

The present invention relates generally to digital phase-locked loop (DPLL) circuits and digitally controlled oscillators (DCOs) used in DPLL circuits.

### BACKGROUND

Digital phase-locked loops (DPLLs) perform frequency and phase control in various electronic systems including frequency synthesizers, clock generators, and wireless communication devices. A DPLL includes a digitally controlled oscillator (DCO) that generates an output signal (e.g., a frequency signal such as a sinusoidal signal) based on digital control words. The DCO output signal is compared with a reference signal to generate an error signal representing frequency or phase differences between the reference signal and the output signal of the DCO. Digital control logic processes the error signal and generates updated control words to adjust the DCO output frequency and phase to match the reference signal.

Traditional DCO implementations face challenges related to frequency resolution, noise performance, and power consumption. The frequency tuning range and step size of a DCO affect its ability to achieve precise frequency control. Phase noise in the DCO output degrades signal quality in communication systems. Additionally, DCO power consumption impacts overall system efficiency, particularly in portable devices operating from limited power sources. Various DCO architectures attempt to balance these performance tradeoffs through different circuit topologies and control schemes.

### SUMMARY

In accordance with an embodiment, a digitally-controlled oscillator (DCO) includes: a digital-to-analog converter (DAC) configured to generate a differential output signal; and a differential varactor circuit comprising: a first input terminal and a second input terminal that are coupled to the DAC and configured to receive the differential output signal of the DAC; a first capacitor terminal and a second capacitor terminal; a first varactor and a second varactor, wherein an anode of the first varactor and an anode of the second varactor are coupled to the second input terminal; a first capacitor coupled between a cathode of the first varactor and the first capacitor terminal; a first resistor coupled between the cathode of the first varactor and the first input terminal; a second capacitor coupled between a cathode of the second varactor and the second capacitor terminal; and a second resistor coupled between the cathode of the second varactor and the first input terminal.

In accordance with an embodiment, a digitally-controlled oscillator (DCO) includes: a digital-to-analog converter (DAC) configured to generate, at a first output terminal of the DAC and a second output terminal of the DAC, a differential output signal; and a varactor circuit comprising: a first input terminal and a second input terminal that are coupled to the first output terminal of the DAC and the second output terminal of the DAC, respectively; a first capacitor terminal and a second capacitor terminal; and a first sub-circuit and a second sub-circuit having a same structure, wherein each of the first sub-circuit and the second sub-circuit comprises: a bias voltage terminal configured to receive a respective bias voltage; a first varactor and a second varactor, wherein an anode of the first varactor and an anode of the second varactor are coupled to the second input terminal; a third varactor and a fourth varactor, wherein an anode of the third varactor and an anode of the fourth varactor are coupled to the first input terminal, wherein a cathode of the first varactor and a cathode of the third varactor are coupled together, and wherein a cathode of the second varactor and a cathode of the fourth varactor are coupled together; a first capacitor coupled between the cathode of the first varactor and the first capacitor terminal of the varactor circuit; a second capacitor coupled between the cathode of the second varactor and the second capacitor terminal of the varactor circuit; a first resistor coupled between the cathode of the first varactor and the bias voltage terminal; and a second resistor coupled between the cathode of the second varactor and the bias voltage terminal.

In accordance with an embodiment, a digital phase-locked loop (DPLL) circuit includes: a time-to-digital converter (TDC) configured to receives a reference frequency signal and a feedback frequency signal, and configured to generate an output signal based on a timing difference between the reference frequency signal and the feedback frequency signal; a digital filter coupled to the TDC and configured to filter the output signal of the TDC and generate a filtered output signal; a digitally controlled oscillator (DCO) coupled to the digital filter and configured to generates an output frequency signal based on the filtered output signal; and a frequency divider coupled to the DCO and configured to generate the feedback frequency signal based on the output frequency signal. The DCO comprises: a digital-to-analog converter (DAC) configured to generate, based on the filtered output signal, a differential output signal at a first output terminal of the DAC and a second output terminal of the DAC; and a varactor circuit comprising: a first input terminal and a second input terminal that are coupled to the first output terminal of the DAC and the second output terminal of the DAC, respectively; a first capacitor terminal and a second capacitor terminal; and a first sub-circuit and a second sub-circuit having a same structure, wherein each of the first sub-circuit and the second sub-circuit comprises: a bias voltage terminal configured to receive a respective bias voltage; a first varactor and a second varactor coupled in an anti-series configuration between a first node and a second node, wherein a third node between the first varactor and the second varactor is coupled to the second input terminal; a third varactor and a fourth varactor coupled in an anti-series configuration between the first node and the second node, wherein a fourth node between the third varactor and the fourth varactor is coupled to the first input terminal; a first capacitor coupled between the first node and the first capacitor terminal of the varactor circuit; a second capacitor coupled between the second node and the second capacitor terminal of the varactor circuit; a first resistor coupled between the first node and the bias voltage terminal; and a second resistor coupled between the second node and the bias voltage terminal.

### BRIEF DESCRIPTION OF THE DRAWINGS

For a more complete understanding of the present invention, and the advantages thereof, reference is now made to the following descriptions taken in conjunction with the accompanying drawings, in which:

FIG. 1 illustrates a block diagram of a digital phase-locked loop (DPLL) system, in an embodiment;

FIG. 2 illustrates a block diagram of a digitally controlled oscillator (DCO), in an embodiment;

FIG. 3 illustrates a differential varactor circuit, in an embodiment;

FIG. 4 illustrates a DCO formed using the differential varactor circuit of FIG. 3, in an embodiment;

FIG. 5 illustrates a portion of a digital-to-analog converter (DAC), in an embodiment;

FIG. 6 illustrates a differential varactor circuit, in another embodiment;

FIG. 7 illustrates a DCO formed using the differential varactor circuit of FIG. 6, in another embodiment;

FIG. 8 illustrates the differential mode capacitance-voltage (CV) characteristics of some varactors of the differential varactor circuit of FIG. 6, in some embodiments;

FIG. 9 illustrates the common mode CV characteristics of some varactors of the differential varactor circuit of FIG. 6, in some embodiments; and

FIG. 10 illustrates the common mode spur rejection performance of the disclosed DCOs, in some embodiments.

### DETAILED DESCRIPTION OF ILLUSTRATIVE EXAMPLES

The making and using of the presently disclosed examples are discussed in detail below. It should be appreciated, however, that the present invention provides many applicable inventive concepts that can be embodied in a wide variety of specific contexts. The specific examples discussed are merely illustrative of specific ways to make and use the invention, and do not limit the scope of the invention. Throughout the discussion herein, unless otherwise specified, the same or similar reference numerals in different figures refer to the same or similar component. For simplicity, details of components with the same or similar reference numeral may not be re-described.

The present disclosure will be described with respect to examples in a specific context, namely DPLL systems and DCOs used in DPLL systems.

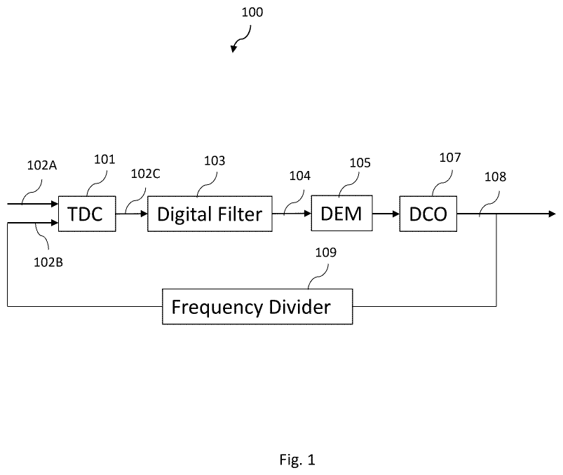

FIG. 1 illustrates a block diagram of a digital phase-locked loop (DPLL) system 100, in an embodiment. The DPLL system 100 includes a time-to-digital converter (TDC) 101 that receives a reference frequency signal 102A (e.g., a reference sinusoidal signal with a known frequency) and a feedback frequency signal 102B. The TDC 101 generates a digital output signal 102C representing the timing difference (e.g., phase difference) between the reference frequency signal 102A and the feedback frequency signal 102B. A digital filter 103 processes the digital output signal 102C from the TDC 101 and generates a filtered digital control signal 104. In various embodiments, the digital filter 103 performs loop filtering operations to establish the loop dynamics of DPLL system 100. The digital filter 103 may be, e.g., a second-order loop filter to track frequency errors in the output signal of the DPLL system 100.

The filtered digital control signal 104 is provided to a dynamic element matching (DEM) circuit 105. The DEM circuit 105 processes the filtered digital control signal 104 to generate a DEM output signal 107. In some embodiments, the DEM circuit 105 reduces mismatch effects in subsequent circuit elements through dynamic averaging techniques. In some embodiments, the DEM circuit 105 is implemented inside (e.g., as a part of) the DCO 107. In some embodiments, the DEM circuit 105 is omitted.

The DEM output signal 107 controls a digitally controlled oscillator (DCO) 107 that generates an output frequency signal 108 (e.g., a sinusoidal signal). The DCO 107 generates the output frequency signal 108 with frequencies determined by digital control words received from the DEM circuit 105 (or from the digital filter 103 if the DEM circuit 105 is omitted). In various embodiments, the DCO 107 includes switched capacitor arrays that adjust the oscillation frequency based on the digital control inputs. In an embodiment, the DCO 107 comprises an LC-tank oscillator with digitally controlled varactors for frequency tuning.

A frequency divider 109 receives the DCO output frequency signal 108 and generates the feedback frequency signal 102B by dividing the frequency of the DCO output signal 108 and converting the divided analog signal into a digital signal (e.g., using a built-in analog-to-digital converter (ADC)). The feedback frequency signal 102B is provided to the TDC 101, thus completing the feedback loop of the DPLL system 100. Various modules of the DPLL system 100, such as the TDC 101, the digital filter 103, the DEM circuit 105, and the frequency divider 109 are known and used in the art, thus additional details are not discussed here. In some embodiments, all or some of the functional blocks of the DPLL system 100 illustrated in FIG. 1 are integrated into a same integrated circuit (IC) die, e.g., on a same semiconductor substrate such a silicon substrate.

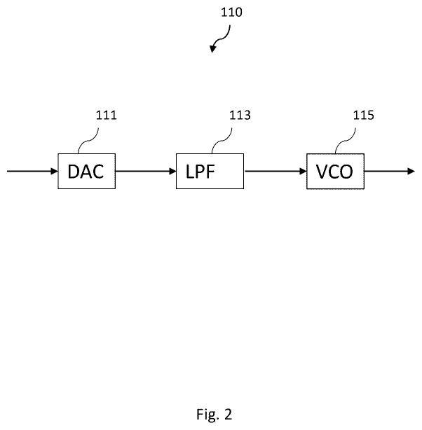

Generally, in a communication system or a radar system, the performance of the local oscillator is important to the overall performance of the system. Specifically, phase noise is a key requirement, and one of the most challenging blocks to design for the communication or radar system is the voltage-controlled oscillator (VCO), or, in the case of a digital PLL, the digitally-controlled oscillator (DCO). The DCO is usually implemented with capacitor bank based tanks, and the digital PLL usually controls an array of capacitor unit cells with a high clock frequency which can reach up to, e.g., hundreds of megahertz to a few gigahertz. Such a high switching frequency can lead to charge injection directly into the DCO tank, which can cause huge spurs in the spectrum of the DCO and, as a consequence, may cause a violation of the emission mask. To alleviate this effect, a solution is to implement the DCO with a DAC+VCO architecture, as illustrated in FIG. 2.

FIG. 2 illustrates a block diagram of a digitally controlled oscillator (DCO) 110, in an embodiment. The DCO 110 illustrated in FIG. 2 can be used as the DCO 107 in FIG. 1. As illustrated in FIG. 2, the DCO 110 includes a digital-to-analog converter (DAC) 111, a low-pass filter (LPF) 113, and a voltage-controlled oscillator (VCO) 115. The LPF 113 is introduced between the DAC 111 and the VCO 115 to provide spur suppression in the DCO output spectrum.

Various options for the LPF 113 are possible, and trade-offs have to be made. For example, a first-order LPF network is simple to implement, but offers limited spur attenuation. Higher-order LPF networks may provide more spur attenuation, but typically require more area for implementation (e.g., due to more capacitors being used).

The present application discloses various embodiments (see, e.g., 300, 500) of the DCO 110. By implementing additional spur suppression directly into the VCO (e.g., 115) and by driving the VCO with a differential DAC output signal, among other features, the disclosed embodiments allow first-order LPF network to be used to avoid the issues (e.g., more area, more noise, and voltage drops) related with higher-order LPF networks, and at the same time, provide excellent spur suppression. Details are discussed hereinafter.

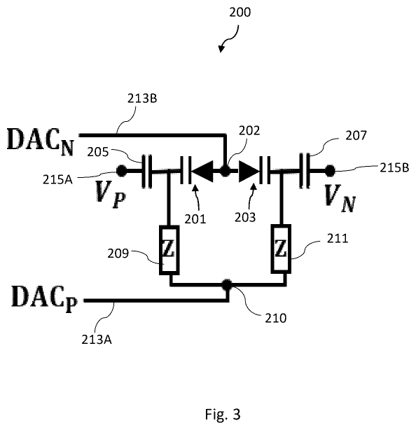

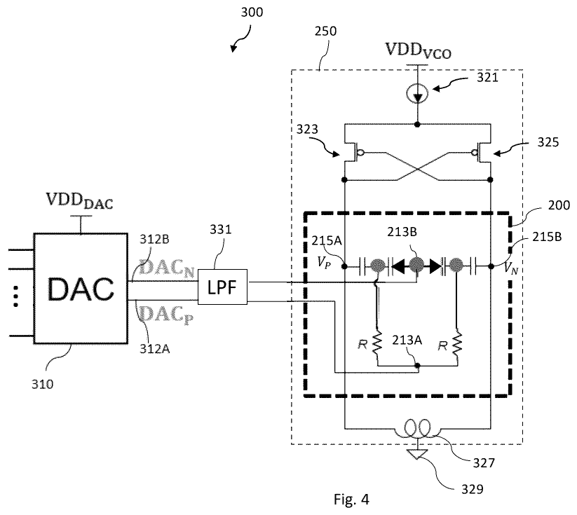

FIG. 3 illustrates a differential varactor circuit 200, in an embodiment. The differential varactor circuit 200 is used as a variable capacitor (e.g., a voltage controlled capacitor) to form the VCO 250 in FIG. 4. As illustrated in FIG. 3, the differential varactor circuit 200 includes an input terminal 213A and an input terminal 213B that are configured to receive a positive signal and a negative signal, respectively, of a differential driving signal (e.g., the differential output signal of the DAC 310 in FIG. 4). The input terminals 213A and 213B are collectively referred to as input terminals 213 or control terminals 213. The differential varactor circuit 200 also includes a capacitor terminal 215A and a capacitor terminal 215B (collectively referred to as capacitor terminals 215). The capacitors terminals 215 correspond to the two terminals of a capacitor.

The differential varactor circuit 200 further includes a varactor 201 and a varactor 203, where an anode of the varactor 201 and an anode of the varactor 203 are coupled to the input terminal 213B. The varactor 201 and the varactor 203 may also be referred to as being coupled in a back-to-back configuration (or in an anti-series configuration). In addition, the differential varactor circuit 200 includes a capacitor 205 coupled between a cathode of the varactor 201 and the capacitor terminal 215A, and includes a resistor 209 coupled between the cathode of the varactor 201 and the input terminal 213A. Furthermore, the differential varactor circuit 200 includes a capacitor 207 coupled between a cathode of the varactor 203 and the capacitor terminal 215B, and includes a resistor 211 coupled between the cathode of the varactor 203 and the input terminal 213A.

In some embodiments, the capacitors 205 and 207 have a same nominal value, and the resistors 209 and 211 have a same nominal value. In some embodiments, both the varactor 201 and the varactor 203 are of the same type of varactors, such as P-type varactors or N-type varactors, and have the same nominal values (e.g., the same nominal tunable capacitance range and the same nominal capacitance-voltage (CV) characteristics). In the discussion herein, a P-type (or N-type) varactor refers to a varactor whose substrate (e.g., silicon) is doped with a P-type (or N-type) dopant.

FIG. 4 illustrates a DCO 300 formed using the differential varactor circuit 200 of FIG. 3, in an embodiment. In FIG. 4, an inductor 327 is coupled to the capacitor terminals 215 of the differential varactor circuit 200. A tap (e.g., a center tap) of the inductor 327 is coupled to a reference voltage node 329, which is configured to be coupled to a reference voltage, such as electrical ground. The differential varactor circuit 200 and the inductor 327 function as the (variable) capacitor and the inductor of the LC tank circuit, respectively.

Transistors 323 and 325 are cross-coupled together, and are coupled to the capacitor terminals 215 of the differential varactor circuit 200 to function as a negative resistor for the LC tank circuit. In the example of FIG. 4, the differential varactor circuit 200, the inductor 327, the cross-coupled transistors 323 and 325, and a current source 321 collectively form a VCO circuit 250. The capacitor terminals 215 of the differential varactor circuit 200 are therefore also the output terminals of the VCO circuit 250.

In the illustrated embodiment of FIG. 4, a gate terminal of the transistor 323 is coupled to a drain terminal of the transistor 325 and the capacitor terminal 215B, a gate terminal of the transistor 325 is coupled to a drain terminal of the transistor 323 and the capacitor terminal 215A, and a source terminal of the transistor 323 and a source terminal of the transistor 325 are coupled to an output terminal of a current source 321. The current source 321 is configured to be coupled between a supply voltage VDD_{VCO} for the VCO circuit 250 and the source terminals of the transistors 323 and 325.

FIG. 4 further illustrates a DAC 310 and a low-pass filter (LPF) 331. The DAC 310 is powered by a supply voltage VDD_{DAC}. The DAC 310 receives the filtered digital control signal 104 (or the output of the DEM circuit 105), and generates, at its output terminals 312A and 312B, a differential output signal that includes a positive signal DAC_{P} and a negative signal DAC_{N}. The positive signal DAC_{P} and the negative signal DAC_{N} are coupled to the input terminals 213 of the differential varactor circuit 200 as a differential driving signal for the VCO 250. Note that in the discussion herein, the positive signal DAC_{P} and the negative signal DAC_{N} are used to distinguish the two constituent signals of the differential output signal of the DAC 310, with the understanding that the signal value (e.g., voltage) of the positive signal DAC_{P} and the signal value of the negative signal DAC_{N} are not necessarily a positive value and a negative value, respectively. For example, the positive signal DAC_{P} may have a value in a range from 0 V to +0.9 V. The negative signal DAC_{N} may have a value within the same range but provides a complementary signal of the positive signal DAC_{P}. For instance, when the positive signal DAC_{P} is +0.9 V, the negative signal DAC_{N} is 0 V, and vice versa. In this way, the positive signal DAC_{P} and the negative signal DAC_{N} provide a differential output signal within a range between −0.9 V to 0.9V. FIG. 4 further illustrates the LPF 331 coupled between the DAC 310 and the VCO circuit 250. The LPF 331 corresponds to the LPF 113 in FIG. 2, and may be implemented as a suitable first-order analog low-pass filter.

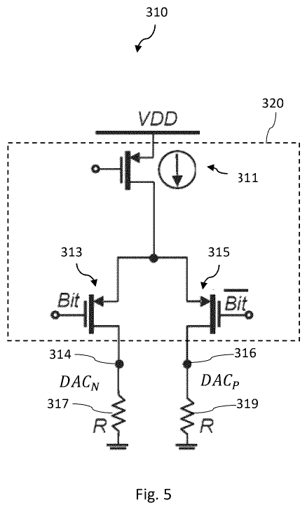

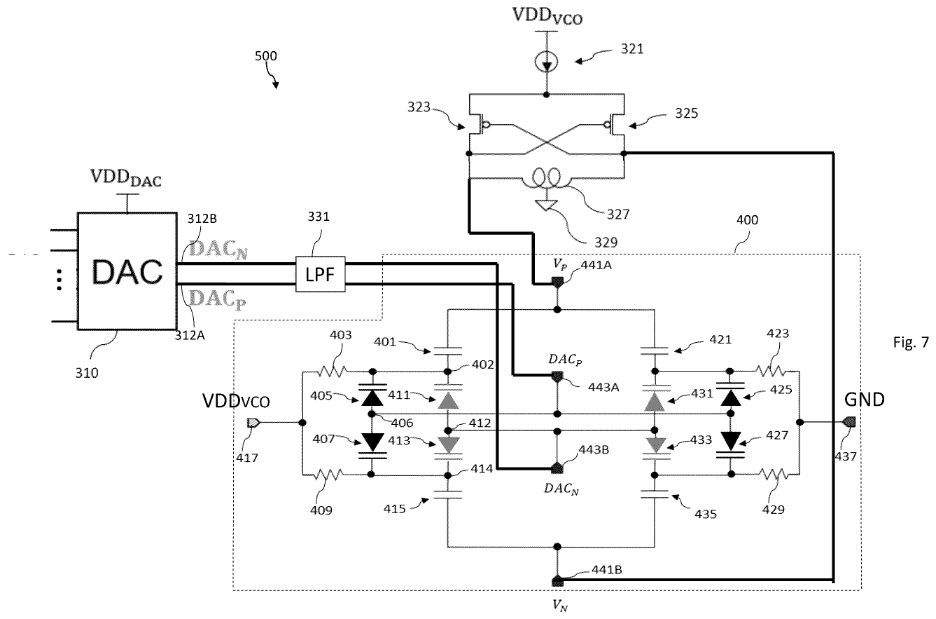

FIG. 5 illustrates a portion of a digital-to-analog converter (DAC) 310, in an embodiment. The DAC 310 may be used as the DAC 310 in FIG. 4 (or FIG. 7). Note the DAC 310 is illustrative and non-limiting. Any other suitable DAC may be used as the DAC 310.

Note that FIG. 5 illustrates a portion of the DAC 310 that converts one bit of the multiple-bit input data into a voltage signal. In the example of FIG. 5, the DAC 310 includes a current source 311, transistors 313 and 315, and resistors 317 and 319. The current source 311 may be, e.g., a current mirror circuit. Current mirror circuit is known and used in the art, thus details are not discussed here. For simplicity, FIG. 5 only shows one of the transistors in the current mirror circuit. As illustrated in FIG. 5, the current source 311 is coupled between a supply voltage VDD (which may correspond to the supply voltage VDD_{DAC} in FIG. 4) and the transistors 313 and 315. The source terminals of the transistors 313 and 315 are coupled to an output terminal of the current source 311. The gate terminals of the transistors 313 and 315 are coupled to a control bit Bit and the inverse of the control bit B̅i̅t̅, respectively. The electrical currents flowing out of the drain terminals of the transistor 313 and 315 are converted into a corresponding portion of the positive signal DAC_{P} and a corresponding portion of the negative signal DAC_{N}, respectively, of the differential output voltage of the DAC 310. In other words, the portion of circuit inside the dashed box 320 in FIG. 5 are replicated for each control bits of the multi-bit input data of the DAC 310, and the corresponding drain terminals of all the replicated circuits are connected to the nodes 314 and 316, respectively. The electrical currents from the drain terminals of all the replicated circuits are summed together and converted into the output voltages of the DAC 310 by the resistors 317 and 319.

Combining a DAC having a differential output signal with a differential varactor circuit to form a DCO circuit, as disclosed herein, has not be disclosed previously. The disclosed architecture, referred to herein as a DAC+VCO differential driving architecture, together with the disclosed differential varactor circuit, achieves many unexpected performance advantages and/or improvements not achievable previously. To appreciate the performance advantages and/or improvements, consider a reference differential varactor circuit. The reference differential varactor circuit is similar to the differential varactor circuit in FIG. 3, but has a second pair of varactors (e.g., a pair of N-type varactors) coupled in the back-to-back configuration and coupled in parallel to the first pair of varactors 201 and 203 (e.g., a pair of P-type varactors). In addition, in the reference differential varactor circuit, the node 210 is configured to be biased with a bias voltage V_{BIAS}, and the node between the second pair of varactors is configured to receive the positive signal of the different output signal of a differential DAC. A reference DCO design can be formed by driving the reference differential varactor circuit with a differential DAC output signal. While the reference DCO design achieves improvement in common-mode rejection, the improvement is limited by mismatches between N-type and P-type varactors. In addition, for the tuning characteristic to be symmetric, the reference DCO design requires that the bias voltage V_{BIAS} to be equal to the middle voltage of the DAC output range. This constraint significantly limits the choice of DAC topology, since not all DAC topologies can satisfy the constraint. In particular, it may force the DAC to adopt topologies which are not optimal in terms of noise performance. Furthermore, since the bias voltage V_{BIAS} in the reference DCO design is to be kept constant, it requires that the DAC output covers the entire voltage range between 0 V and 2V_{BIAS}, which is typically a wide range and can be achieved only at the expense of reduced DAC linearity, since there is a tradeoff between DAC range and DAC linearity.

In the disclosed DAC+VCO differential driving architecture (see, e.g., FIG. 4), the DAC output differential voltage determines the capacitance variation of the differential varactor circuit, while the DAC output common mode voltage (e.g., the value of the positive voltage or the value of the negative voltage) does not cause capacitance variation. Unlike the reference DCO design, the common-mode rejection of the disclosed DCO design does not rely anymore on the matching between N-type and P-type varactors, so the common-mode rejection is higher. In addition to the common-mode rejection capabilities, the disclosed DAC+VCO differential driving architecture also offers several unprecedented advantages. For example, the disclosed DAC+VCO differential driving architecture avoids the above performance issues associated with the reference DCO design while at the same time, achieves higher spur suppression, better supply pushing, and good varactor linearity, as discussed hereinafter.

First, since the capacitances of the disclosed varactor circuits are independent of the DAC output common mode voltage, there is no longer a constraint on the middle voltage of DAC output range. As a result, the DAC topology can be chosen freely in order to obtain improved noise performance. For example, a PMOS DAC, which was not possible previously due to the constraint on the middle voltage, can now be used to achieve improved noise performance. Second, at the same DAC_{P}−DAC_{N} range as in the reference DCO design, the disclosed DAC+VCO differential driving architecture allows half the voltage range for the DAC output, which leads to superior DAC linearity. Third, since the input terminals of the disclosed differential varactor circuits are both connected to the DAC output terminals, any disturbances (e.g., noises) on the DAC supply voltage VDD_{DAC} behaves like a common-mode signal and is rejected by the differential varactor circuit, and as a result, better supply pushing from the DAC supply voltage VDD_{DAC} is achieved. Lastly, supply pushing from the VCO supply voltage VDD_{VCO} is also improved, because no node of the differential varactor circuit is directly connected to the VCO supply voltage VDD_{VCO}. Note that in the reference DCO design, the node 210 (for receiving bias voltage V_{BIAS}) is typically shorted to the VCO supply voltage VDD_{VCO}, thus leading to a much higher supply pushing from the VCO supply voltage VDD_{VCO}. It is also worth noting that all of the above advantages are obtained with little or no additional power consumption or area penalty compared with conventional solutions.

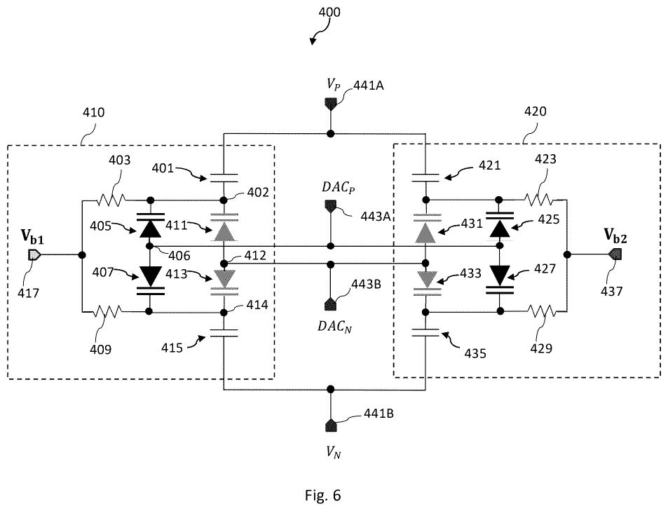

FIG. 6 illustrates a differential varactor circuit 400, in another embodiment. The differential varactor circuit 400 and DCO formed using the differential varactor circuit 400 achieve similar advantages as discussed above. In addition, the differential varactor circuit 400 achieves higher VCO linearity than the differential varactor circuit 200.

Referring to FIG. 6, the differential varactor circuit 400 includes an input terminal 443A and an input terminal 443B (collectively referred to as input terminals 443 or control terminals 443) that are configured to receive the positive signal (e.g., DAC_{P}) and the negative signal (e.g., DAC_{N}), respectively, of a differential signal (e.g., the DAC output differential signal). The differential varactor circuit 400 also includes a capacitor terminal 441A and a capacitor terminal 441B (collectively referred to as capacitor terminals 441). The differential varactor circuit 400 further includes a sub-circuit 410 and a sub-circuit 420 having a same structure. In other words, the sub-circuit 420 is a duplicate (e.g., is mirror symmetric) of the sub-circuit 410. In the example of FIG. 6, components in the sub-circuits 410 and 420 are labeled with different numerals, with the understanding that corresponding components have the same nominal value(s) and/or the same nominal electrical characteristics. Note that during normal operation of the differential varactor circuit 400 (e.g., functioning as part of a DCO), the sub-circuits 410 and 420 are biased with different bias voltages (e.g., V_{b1} and V_{b2}) at their respective biasing voltage terminals 417 and 437, in some embodiments.

As illustrated in FIG. 6, the sub-circuit 410 includes: a bias voltage terminal 417 configured to receive a bias voltage V_{b1}; a pair of varactors 411 and 413 (e.g., P-type varactors) connected in the back-to-back configuration, where an anode of the varactor 411 and an anode of the varactor 413 are coupled to the input terminal 443B; and a pair of varactors 405 and 407 (e.g., N-type varactors) connected in the back-to-back configuration, where an anode of the varactor 405 and an anode of the varactor 407 are coupled to the input terminal 443A. A cathode of the varactor 411 and a cathode of the varactor 405 are coupled together at a node 402, and a cathode of the varactor 413 and a cathode of the varactor 407 are coupled together at a node 414. The sub-circuit 410 further includes: a capacitor 401 coupled between the node 402 and the capacitor terminal 441A; a capacitor 415 coupled between the node 414 and the capacitor terminal 441B; a resistor 403 coupled between the node 402 and the bias voltage terminal 417; and a resistor 409 coupled between the node 414 and the bias voltage terminal 417. The sub-circuit 420 in FIG. 6 is a mirror-symmetric implementation of the sub-circuit 410, with varactors 431 and 433 being P-type varactors, and the varactors 425 and 427 being N-type varactors. Details are the same as or similar to the sub-circuit 410, thus not repeated here.

Note that in the example of FIG. 6, the concept of the differential driving showed above in FIGS. 3 and 4 is maintained, but each of the sub-circuits 410 and 420 has two different types of varactors (e.g., P-type varactors and N-type varactors). In addition, the differential signals drive the varactors of the differential varactor circuit 400 in a different way. For example, DAC output signals DAC_{N} and DAC_{P} are connected to the anodes of the P-type varactors (e.g. PMOS varactors) and N-type varactors (e.g., NMOS varactors), respectively.

Furthermore, as mentioned above, during normal operation, the sub-circuit 410 is biased with a bias voltage of, e.g., VDD_{VCO} and the sub-circuit 420 is biased with a bias voltage of, e.g., GND.

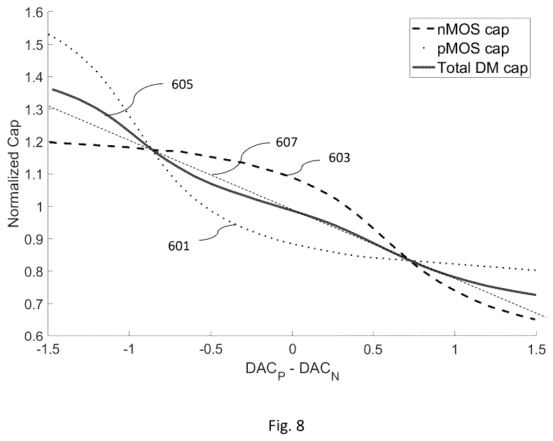

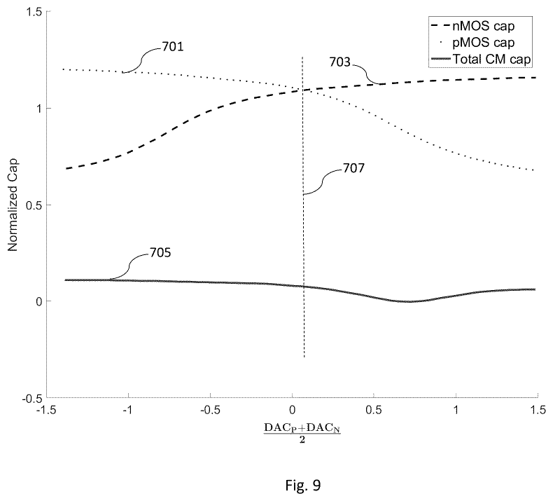

The differential varactor circuit 400 achieves improved linearity by compensating the non-linearity of the N-type varactors with that of the P-type varactors, and vice versa, in some embodiments. To achieve proper compensation, the N-type varactors and the P-type varactors in a sub-circuit 410 (or 420) are designed to have specular nominal capacitance-voltage (CV) characteristics. In addition, a good common mode spur rejection is achieved by designing a first type (e.g., P-type) of varactors in the sub-circuits 410 and a second opposing type (e.g., N-type) of varactors in the sub-circuit 420 to have specular nominal CV characteristics. Additional details are discussed hereinafter with reference to FIGS. 8 and 9.

FIG. 7 illustrates a DCO 500 formed using the differential varactor circuit 400 of FIG. 6, in another embodiment. The DCO 500 is formed by replacing the differential varactor circuit 200 in FIG. 4 with the differential varactor circuit 400. For example, the positive output signal DAC_{P} and the negative output signal DAC_{N} of the differential output signal of the DAC 310 are filtered by the LPF 331, then sent to the input terminals 443A and 443B of the differential varactor circuit 400, respectively. The capacitor terminals 441A and 441B of the differential varactor circuit 400 in FIG. 7 correspond to the capacitor terminals 215A and 215B of the differential varactor circuit 200 in FIG. 4, respectively. Noticeably, in FIG. 7, bias terminals 417 and 437 of the differential varactor circuit 400 are biased with different bias voltages (e.g., VDD_{VCO} and GND, respectively).

FIG. 8 illustrates the differential mode capacitance-voltage (CV) characteristics of the varactors of the differential varactor circuit of FIG. 6, in some embodiments. The x-axis shows the voltage difference between the positive output signal DAC_{P} and the negative output signal DAC_{N} of the DAC 310, and the y-axis shows the normalized capacitance. In particular, the curve 601 illustrates the normalized total capacitance of the P-type varactors 411 and 413 in the sub-circuit 410 versus voltage DAC_{P}−DAC_{N}, and the curve 603 illustrates the normalized total capacitance of the N-type varactors 405 and 407 in the same sub-circuit versus voltage DAC_{P}−DAC_{N}. The curve 605 shows the sum of the curves 601 and 603. Ideally, the CV characteristic shown by the curve 601 is specular with respect to the CV characteristics shown by the curve 603. In other words, the nominal CV characteristics of the P-type varactors 411 and 413 is specular with respect to the nominal CV characteristics of the N-type varactors 405 and 407. Note that the term “specular” refers to the symmetry of the curves 601 and 603 about a center axis 607. The curves 601 and 603 in FIG. 8 illustrate the measured CV characteristics of a differential varactor circuit 400, and due to non-ideal conditions, such as parasitic capacitances, components values deviating from their nominal values, the curves 601 and 603 are not perfectly symmetric about the center axis 607. As a result, the curve 605 does not overlap completely with the center axis 607. Under ideal conditions, the curve 605 would overlap completely with the center axis 607.

By designing the nominal CV characteristics of the P-type varactors 411 and 413 to be specular with respect to the nominal CV characteristics of the N-type varactors 405 and 407, the non-linearity of the P-type varactors 411 and 413 counteracts (e.g. compensates) the non-linearity of the N-type varactors 405 and 407, and therefore, the total capacitance of the varactors in the sub-circuit 410 achieves a high level of linearity, as illustrated by the curve 605 (under non-ideal conditions) or the center axis 607 (under ideal conditions). Skilled artisans will readily appreciate that the nominal CV characteristics of the P-type varactors 431 and 433 should also be designed to be specular with respect to the nominal CV characteristics of the N-type varactors 425 and 427 in the sub-circuit 420, in order to achieve a high level of linearity for the total capacitance of the varactors in the sub-circuit 420.

FIG. 9 illustrates the common mode CV characteristics of some varactors of the differential varactor circuit of FIG. 6 in common-mode operation, in some embodiments. The x-axis shows the voltage (DAC_{P}+DAC_{N})/2, and the y-axis shows the normalized capacitance. In particular, the curve 701 illustrates the normalized total capacitance of the P-type varactors 411 and 413 in the sub-circuit 410 versus the voltage (DAC_{P}+DAC_{N})/2, and the curve 703 illustrates the normalized total capacitance of the N-type varactors 425 and 427 in the sub-circuit 420 versus the voltage (DAC_{P}+DAC_{N})/2. The curve 705 shows the sum of the curves 701 and 703. Ideally, the CV characteristic shown by the curve 701 is specular with respect to the CV characteristics shown by the curve 703 about a center axis 707 (e.g., a vertical line). In other words, the nominal common-mode CV characteristics of the P-type varactors 411 and 413 is specular with respect to the nominal common-mode CV characteristics of the N-type varactors 425 and 427. The curves 701 and 703 in FIG. 9 illustrate the measured CV characteristics of a differential varactor circuit 400, and due to non-ideal conditions, such as parasitic capacitances, components values deviating from their nominal values, the curves 701 and 703 are not perfectly symmetric about the center axis 707. As a result, the curve 705 is not a perfectly flat line (e.g., a horizontal line). Under ideal conditions, the curve 705 would be a perfectly flat line.

By designing the nominal common-mode CV characteristics of the P-type varactors 411 and 413 to be specular with respect to the nominal common-mode CV characteristics of the N-type varactors 425 and 427, the non-linearity of the P-type varactors in the sub-circuit 410 counteracts (e.g. compensates) the non-linearity of the N-type varactors in the sub-circuit 420 in common-mode. Skilled artisans will readily appreciate that the nominal common-mode CV characteristics of the P-type varactors 431 and 433 in the sub-circuit 420 should also be designed to be specular with respect to the nominal common-mode CV characteristics of the N-type varactors 405 and 407 in the sub-circuit 410. This achieves a high common-mode rejection for the DCO formed.

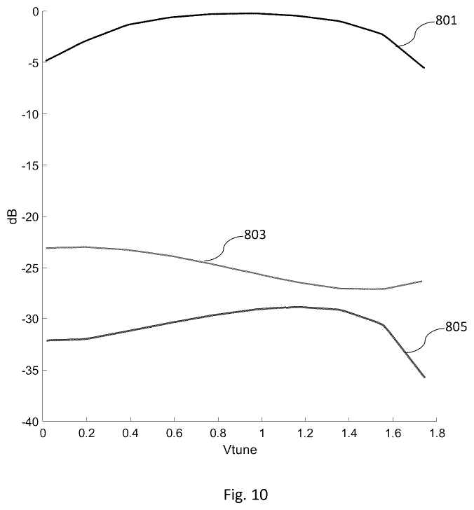

FIG. 10 illustrates the common mode spur rejection performance of the disclosed DCOs, in some embodiments. In FIG. 10, curves 805 and 803 illustrate the common mode spur rejection achieved by the DCOs 300 and 500, respectively. For comparison, curve 801 shows the performance of a DCO formed using a conventional singled-ended varactor. The X-axis of FIG. 10 shows the tuning voltage, and the Y-axis of FIG. 10 shows the common mode spur rejection. It is seen from FIG. 10 that both DCOs 300 and 500 achieve significantly improved common mode spur rejection compared with the conventional DCO. In the example of FIG. 10, the DCO 300 achieves more common mode spur rejection than the DCO 500, while the DCO 500 achieves more uniform common mode spur rejection.

Embodiments may achieve advantages as described below. By combing a differential DAC with the disclosed differential varactor circuit to form DCO, the disclosed DAC+VCO differential driving architecture allows freedom in choosing the DAC topology in order to obtain improved noise performance. In addition, the disclosed DAC+VCO differential driving architecture does not have a constraint on the voltage range for the DAC output, which allows DAC with lower voltage output range and superior linearity be used. Furthermore, noises on the power supplies are rejected like a common-mode signal by the disclosed differential varactor circuits, and as a result, better supply pushing from the DAC and DCO supply voltages is achieved. The above advantages are obtained with little or no additional power consumption or area penalty compared with conventional solutions.

Examples of the present invention are summarized here. Other examples can also be understood from the entirety of the specification and the claims filed herein.

Example 1. In accordance with an embodiment, a digitally-controlled oscillator (DCO) includes: a digital-to-analog converter (DAC) configured to generate a differential output signal; and a differential varactor circuit comprising: a first input terminal and a second input terminal that are coupled to the DAC and configured to receive the differential output signal of the DAC; a first capacitor terminal and a second capacitor terminal; a first varactor and a second varactor, wherein an anode of the first varactor and an anode of the second varactor are coupled to the second input terminal; a first capacitor coupled between a cathode of the first varactor and the first capacitor terminal; a first resistor coupled between the cathode of the first varactor and the first input terminal; a second capacitor coupled between a cathode of the second varactor and the second capacitor terminal; and a second resistor coupled between the cathode of the second varactor and the first input terminal.

Example 2. The DCO of Example 1, wherein the first input terminal and the second input terminal of the differential varactor circuit are configured to receive a positive signal of the differential output signal and a negative signal of the differential output signal, respectively.

Example 3. The DCO of Example 2, wherein the first varactor and the second varactor are both N-type varactors or P-type varactors.

Example 4. The DCO of Example 2, further comprising an inductor coupled between the first capacitor terminal and the second capacitor terminal of the differential varactor circuit.

Example 5. The DCO of Example 2, further comprising: a current source; a first transistor; and a second transistor, wherein a first gate terminal of the first transistor is coupled to a drain terminal of the second transistor and the second capacitor terminal of the differential varactor circuit, wherein a gate terminal of the second transistor is coupled to a drain terminal of the first transistor and the first capacitor terminal of the differential varactor circuit, and wherein a source terminal of the first transistor and a source terminal of the second transistor are coupled to an output terminal of the current source.

Example 6. In accordance with an embodiment, a digitally-controlled oscillator (DCO) includes: a digital-to-analog converter (DAC) configured to generate, at a first output terminal of the DAC and a second output terminal of the DAC, a differential output signal; and a varactor circuit comprising: a first input terminal and a second input terminal that are coupled to the first output terminal of the DAC and the second output terminal of the DAC, respectively; a first capacitor terminal and a second capacitor terminal; and a first sub-circuit and a second sub-circuit having a same structure, wherein each of the first sub-circuit and the second sub-circuit comprises: a bias voltage terminal configured to receive a respective bias voltage; a first varactor and a second varactor, wherein an anode of the first varactor and an anode of the second varactor are coupled to the second input terminal; a third varactor and a fourth varactor, wherein an anode of the third varactor and an anode of the fourth varactor are coupled to the first input terminal, wherein a cathode of the first varactor and a cathode of the third varactor are coupled together, and wherein a cathode of the second varactor and a cathode of the fourth varactor are coupled together; a first capacitor coupled between the cathode of the first varactor and the first capacitor terminal of the varactor circuit; a second capacitor coupled between the cathode of the second varactor and the second capacitor terminal of the varactor circuit; a first resistor coupled between the cathode of the first varactor and the bias voltage terminal; and a second resistor coupled between the cathode of the second varactor and the bias voltage terminal.

Example 7. The DCO of Example 6, wherein the DAC is configured to generate, at the first output terminal of the DAC and the second output terminal of the DAC, a positive signal and a negative signal, respectively, of the differential output signal.

Example 8. The DCO of Example 7, wherein the first varactor and the second varactor are P-type varactors, and wherein the third varactor and the fourth varactor are N-type varactors.

Example 9. The DCO of Example 8, wherein the first varactor and the second varactor have a first nominal capacitance-voltage (C-V) characteristics, wherein the third varactor and the fourth varactor have a second nominal C-V characteristics, wherein the first nominal C-V characteristics is specular with respect to the second nominal C-V characteristics.

Example 10. The DCO of Example 8, wherein the bias voltage terminal of the first sub-circuit and the bias voltage terminal of the second sub-circuit are configured to receive different bias voltages.

Example 11. The DCO of Example 8, wherein the bias voltage terminal of the first sub-circuit is configured to receive a supply voltage, and the bias voltage terminal of the second sub-circuit is configured to be coupled to electrical ground.

Example 12. The DCO of Example 6, further comprising: an inductor coupled between the first capacitor terminal and the second capacitor terminal of the varactor circuit; and a first transistor and a second transistor that are cross-coupled together, wherein a drain terminal of the first transistor and a drain terminal of the second transistor are coupled to the first capacitor terminal and the second capacitor terminal, respectively, of the varactor circuit.

Example 13. The DCO of Example 12, further comprising a current source, wherein a source terminal of the first transistor and a source terminal of the second transistor are coupled to an output terminal of the current source.

Example 14. In accordance with an embodiment, a digital phase-locked loop (DPLL) circuit includes: a time-to-digital converter (TDC) configured to receives a reference frequency signal and a feedback frequency signal, and configured to generate an output signal based on a timing difference between the reference frequency signal and the feedback frequency signal; a digital filter coupled to the TDC and configured to filter the output signal of the TDC and generate a filtered output signal; a digitally controlled oscillator (DCO) coupled to the digital filter and configured to generates an output frequency signal based on the filtered output signal; and a frequency divider coupled to the DCO and configured to generate the feedback frequency signal based on the output frequency signal. The DCO comprises: a digital-to-analog converter (DAC) configured to generate, based on the filtered output signal, a differential output signal at a first output terminal of the DAC and a second output terminal of the DAC; and a varactor circuit comprising: a first input terminal and a second input terminal that are coupled to the first output terminal of the DAC and the second output terminal of the DAC, respectively; a first capacitor terminal and a second capacitor terminal; and a first sub-circuit and a second sub-circuit having a same structure, wherein each of the first sub-circuit and the second sub-circuit comprises: a bias voltage terminal configured to receive a respective bias voltage; a first varactor and a second varactor coupled in an anti-series configuration between a first node and a second node, wherein a third node between the first varactor and the second varactor is coupled to the second input terminal; a third varactor and a fourth varactor coupled in an anti-series configuration between the first node and the second node, wherein a fourth node between the third varactor and the fourth varactor is coupled to the first input terminal; a first capacitor coupled between the first node and the first capacitor terminal of the varactor circuit; a second capacitor coupled between the second node and the second capacitor terminal of the varactor circuit; a first resistor coupled between the first node and the bias voltage terminal; and a second resistor coupled between the second node and the bias voltage terminal.

Example 15. The DPLL circuit of Example 14, wherein the bias voltage terminal of the first sub-circuit and the bias voltage terminal of the second sub-circuit are configured to be biased with different voltages.

Example 16. The DPLL circuit of Example 14, wherein the different output signal of the DAC comprises a positive signal and a negative signal, wherein the DAC is configured to generate the positive signal and the negative signal at the first output terminal of the DAC and the second output terminal of the DAC, respectively.

Example 17. The DPLL circuit of Example 16, wherein the first varactor and the second varactor are P-type varactors, and the third varactor and the fourth varactor are N-type varactors.

Example 18. The DPLL circuit of Example 14, wherein the DCO further comprises an inductor coupled between the first capacitor terminal of the varactor circuit and the second capacitor terminal of the varactor circuit.

Example 19. The DPLL circuit of Example 18, wherein the DCO further comprises: a current source; a first transistor; and a second transistor, wherein a first gate terminal of the first transistor is coupled to a drain terminal of the second transistor and the second capacitor terminal of the varactor circuit, wherein a gate terminal of the second transistor is coupled to a drain terminal of the first transistor and the first capacitor terminal of the varactor circuit, and wherein a source terminal of the first transistor and a source terminal of the second transistor are coupled to an output terminal of the current source.

Example 20. The DPLL circuit of Example 14, further comprising a dynamic element matching (DEM) circuit coupled between the digital filter and the DCO.

While this invention has been described with reference to illustrative examples, this description is not intended to be construed in a limiting sense. Various modifications and combinations of the illustrative examples, as well as other examples of the invention, will be apparent to persons skilled in the art upon reference to the description. It is therefore intended that the appended claims encompass any such modifications or examples.

1. A digitally-controlled oscillator (DCO) comprising:
a digital-to-analog converter (DAC) configured to generate a differential output signal; and
a differential varactor circuit comprising:
a first input terminal and a second input terminal that are coupled to the DAC and configured to receive the differential output signal of the DAC, wherein the first input terminal and the second input terminal of the differential varactor circuit are configured to receive a positive signal of the differential output signal and a negative signal of the differential output signal, respectively;
a first capacitor terminal and a second capacitor terminal;
a first varactor and a second varactor, wherein an anode of the first varactor and an anode of the second varactor are coupled to the second input terminal;
a first capacitor coupled between a cathode of the first varactor and the first capacitor terminal;
a first resistor coupled between the cathode of the first varactor and the first input terminal;
a second capacitor coupled between a cathode of the second varactor and the second capacitor terminal; and
a second resistor coupled between the cathode of the second varactor and the first input terminal.

2. (canceled)

3. The DCO of claim 1, wherein the first varactor and the second varactor are both N-type varactors or P-type varactors.

4. The DCO of claim 1, further comprising an inductor coupled between the first capacitor terminal and the second capacitor terminal of the differential varactor circuit.

5. The DCO of claim 1, further comprising:
a current source;
a first transistor; and
a second transistor, wherein a gate terminal of the first transistor is coupled to a drain terminal of the second transistor and the second capacitor terminal of the differential varactor circuit, wherein a gate terminal of the second transistor is coupled to a drain terminal of the first transistor and the first capacitor terminal of the differential varactor circuit, and wherein a source terminal of the first transistor and a source terminal of the second transistor are coupled to an output terminal of the current source.

6. A digitally-controlled oscillator (DCO) comprising:
a digital-to-analog converter (DAC) configured to generate, at a first output terminal of the DAC and a second output terminal of the DAC, a differential output signal; and
a varactor circuit comprising:
a first input terminal and a second input terminal that are coupled to the first output terminal of the DAC and the second output terminal of the DAC, respectively;
a first capacitor terminal and a second capacitor terminal; and
a first sub-circuit and a second sub-circuit having a same structure, wherein each of the first sub-circuit and the second sub-circuit comprises:
a bias voltage terminal configured to receive a respective bias voltage;
a first varactor and a second varactor, wherein an anode of the first varactor and an anode of the second varactor are coupled to the second input terminal;
a third varactor and a fourth varactor, wherein an anode of the third varactor and an anode of the fourth varactor are coupled to the first input terminal, wherein a cathode of the first varactor and a cathode of the third varactor are coupled together, and wherein a cathode of the second varactor and a cathode of the fourth varactor are coupled together;
a first capacitor coupled between the cathode of the first varactor and the first capacitor terminal of the varactor circuit;
a second capacitor coupled between the cathode of the second varactor and the second capacitor terminal of the varactor circuit;
a first resistor coupled between the cathode of the first varactor and the bias voltage terminal; and
a second resistor coupled between the cathode of the second varactor and the bias voltage terminal.

7. The DCO of claim 6, wherein the DAC is configured to generate, at the first output terminal of the DAC and the second output terminal of the DAC, a positive signal and a negative signal, respectively, of the differential output signal.

8. The DCO of claim 7, wherein the first varactor and the second varactor are P-type varactors, and wherein the third varactor and the fourth varactor are N-type varactors.

9. The DCO of claim 8, wherein the first varactor and the second varactor have a first nominal capacitance-voltage (CV) characteristic, wherein the third varactor and the fourth varactor have a second nominal CV characteristic, wherein the first nominal CV characteristic is specular with respect to the second nominal CV characteristic.

10. The DCO of claim 8, wherein the bias voltage terminal of the first sub-circuit and the bias voltage terminal of the second sub-circuit are configured to receive different bias voltages.

11. The DCO of claim 8, wherein the bias voltage terminal of the first sub-circuit is configured to receive a supply voltage, and the bias voltage terminal of the second sub-circuit is configured to be coupled to electrical ground.

12. The DCO of claim 6, further comprising:
an inductor coupled between the first capacitor terminal and the second capacitor terminal of the varactor circuit; and
a first transistor and a second transistor that are cross-coupled together, wherein a drain terminal of the first transistor and a drain terminal of the second transistor are coupled to the first capacitor terminal and the second capacitor terminal, respectively, of the varactor circuit.

13. The DCO of claim 12, further comprising a current source, wherein a source terminal of the first transistor and a source terminal of the second transistor are coupled to an output terminal of the current source.

14. A digital phase-locked loop (DPLL) circuit comprising:
a time-to-digital converter (TDC) configured to receive a reference frequency signal and a feedback frequency signal, and configured to generate an output signal based on a timing difference between the reference frequency signal and the feedback frequency signal;
a digital filter coupled to the TDC and configured to filter the output signal of the TDC and generate a filtered output signal;
a digitally controlled oscillator (DCO) coupled to the digital filter and configured to generate an output frequency signal based on the filtered output signal; and
a frequency divider coupled to the DCO and configured to generate the feedback frequency signal based on the output frequency signal,
wherein the DCO comprises:
a digital-to-analog converter (DAC) configured to generate, based on the filtered output signal, a differential output signal at a first output terminal of the DAC and a second output terminal of the DAC; and
a varactor circuit comprising:
a first input terminal and a second input terminal that are coupled to the first output terminal of the DAC and the second output terminal of the DAC, respectively;
a first capacitor terminal and a second capacitor terminal; and
a first sub-circuit and a second sub-circuit having a same structure, wherein each of the first sub-circuit and the second sub-circuit comprises:
a bias voltage terminal configured to receive a respective bias voltage;
a first varactor and a second varactor coupled in an anti-series configuration between a first node and a second node, wherein a third node between the first varactor and the second varactor is coupled to the second input terminal;
a third varactor and a fourth varactor coupled in an anti-series configuration between the first node and the second node, wherein a fourth node between the third varactor and the fourth varactor is coupled to the first input terminal;
a first capacitor coupled between the first node and the first capacitor terminal of the varactor circuit;
a second capacitor coupled between the second node and the second capacitor terminal of the varactor circuit;
a first resistor coupled between the first node and the bias voltage terminal; and
a second resistor coupled between the second node and the bias voltage terminal.

15. The DPLL circuit of claim 14, wherein the bias voltage terminal of the first sub-circuit and the bias voltage terminal of the second sub-circuit are configured to be biased with different voltages.

16. The DPLL circuit of claim 14, wherein the differential output signal of the DAC comprises a positive signal and a negative signal, wherein the DAC is configured to generate the positive signal and the negative signal at the first output terminal of the DAC and the second output terminal of the DAC, respectively.

17. The DPLL circuit of claim 16, wherein the first varactor and the second varactor are P-type varactors, and the third varactor and the fourth varactor are N-type varactors.

18. The DPLL circuit of claim 14, wherein the DCO further comprises an inductor coupled between the first capacitor terminal of the varactor circuit and the second capacitor terminal of the varactor circuit.

19. The DPLL circuit of claim 18, wherein the DCO further comprises:
a current source;
a first transistor; and
a second transistor, wherein a gate terminal of the first transistor is coupled to a drain terminal of the second transistor and the second capacitor terminal of the varactor circuit, wherein a gate terminal of the second transistor is coupled to a drain terminal of the first transistor and the first capacitor terminal of the varactor circuit, and wherein a source terminal of the first transistor and a source terminal of the second transistor are coupled to an output terminal of the current source.

20. The DPLL circuit of claim 14, further comprising a dynamic element matching (DEM) circuit coupled between the digital filter and the DCO.
